(19) United States
(12) Patent Application Publication
(10) Pub. No.: US 2014/0096715 A1
(43) Pub. Date: Apr. 10, 2014

(54) Apparatus for filtration and gas-vapor mixing in thin film deposition

(71) Applicant: MSP Corporation, Shoreview, MN (US)

(72) Inventors: Benjamin Y.H. Liu, North Oaks, MN (US); Yamin Ma, Roseville, MN (US); Thuc Dinh, Shakopee, MN (US)

(73) Assignee: MSP Corporation, Shoreview, MN (US)

(21) Appl. No.: 14/107,718

(22) Filed: Dec. 16, 2013

Related U.S. Application Data
(63) Continuation of application No. 12/471,831, filed on May 26, 2009.
(60) Provisional application No. 61/057,271, filed on May 30, 2008.

(51) Int. Cl. B01D 46/00; F22B 1/28; C23C 16/44

(52) U.S. Cl. CPC B01D 46/0027; C23C 16/4402; F22B 1/28
USPC 118/722; 55/495; 55/490.1; 55/482; 392/386

(57) ABSTRACT

An apparatus removes particles from a gas/vapor mixture while at the same time improves the uniformity of gas/vapor mixture to create a more uniformly-mixed mixture stream for thin film deposition and semiconductor device fabrication.

### CROSS-REFERENCE TO RELATED APPLICATION

The present application is based on and claims the benefit of U.S. provisional patent application Ser. No. 61/057,271, filed May 30, 2008, the content of which is hereby incorporated by reference in its entirety.

### BACKGROUND OF THE DISCLOSURE

The present disclosure relates to an apparatus for removing particles from a gas/vapor mixture stream while at the same time improving the uniformity of the thin film being formed on a substrate. The apparatus is particularly useful for fabricating integrated circuit devices on silicon and other semiconducting wafers. It is suitable for a variety of thin film deposition processes, including chemical vapor deposition (CVD), atomic layer deposition (ALD), plasma enhanced CVD (PE-CVD) processes, among others. In these processes a liquid precursor is often vaporized to form vapor in a carrier gas. The resulting gas/vapor mixture is then introduced into a deposition chamber for thin film deposition on a substrate.

Vaporization of a liquid or solid precursor to form vapor is often accompanied by the formation of particles. These particles can range in size from a few nanometers (nm) in diameter to hundreds or thousands of nanometers. Particles carried by the gas/vapor mixture stream from a vaporization apparatus into the deposition chamber can deposit on the wafer surface to cause harmful effects, including the loss of product yield. Particulate contamination is a major cause of product yield loss in semiconductor device fabrication. Left uncontrolled, particle contamination can severely impact the productivity and profitability of the semiconductor device fab.

One known method of reducing particulate contamination of wafers is to place a filter in the process gas stream to remove particles and prevent them from being carried by the gas/vapor stream into the deposition chamber. Precursor vaporization systems such as those described in U.S. Pat. No. 6,409,839 includes a filter for particle removal, thus insuring that the output gas/vapor mixture will be substantially free of particulate contaminants. Since hot vapor can condense in a cold filter, the filter must be heated. The vaporization apparatus described in U.S. Pat. No. 6,409,839 has a built-in filter that is heated to substantially the same temperature as the vaporizer system itself, thus minimizing potential vapor condensation on an unheated or insufficiently heated filter.

Another aspect of the vaporization process is the need to have a gas/vapor mixture that is uniform in gas/vapor composition across the mixture stream. Non-uniform mixing of the gas and vapor can create variation in the mixing ratio of the gas and vapor that can lead to thickness variations in the deposited film. When hundreds, or even thousands, of integrated device chips are made on a single 300-mm diameter wafer, variation in film thickness across the wafer or from wafer to wafer will cause variation in the device quality, sometimes causing device failure that can lead to a product yield loss.

### SUMMARY OF THE DISCLOSURE

The present disclosure relates to an apparatus for removing particles from a gas/vapor mixture while at the same time improving the uniformity of gas/vapor mixture to create a more uniformly-mixed mixture stream for thin film deposition and semiconductor device fabrication.

In one embodiment of the apparatus, a filter is placed inside an enclosure designed to promote the uniform mixing of the gas and vapor while the mixture stream passes through the apparatus for particle removal. The enclosure is electrically heated and provided with a temperature sensor to permit the enclosure and the filter enclosed therein to be heated to a substantially uniform temperature to prevent vapor condensation in the apparatus. Mixing is created by centrifugal force by forcing the gas/vapor mixture stream to undergo a change in flow direction without using any external power or moving parts. Mixing is also created by using a turbulent jet formed within the filtration apparatus.

In the preferred embodiment, the inlet and outlet tubes are perpendicular to the cylindrically-shaped enclosure and designing the apparatus in such a manner as to cause the gas/vapor mixture to undergo two right angle turns of approximately 180 degrees in the total angular change in flow direction to create the needed centrifugal force for mixing. It also uses a turbulent jet to further enhance the mixing of the gas and vapor.

In another embodiment, the apparatus has internal passageways that cause the gas stream to undergo a total of six right-angle turns of approximately 90 degrees each, for a total cumulative directional change of 540 degrees.

Yet in another embodiment, two parallel filtration and mixing systems are incorporated into the same apparatus to provide twice the flow capacity of a single filtration and mixing system.

### BRIEF DESCRIPTION OF THE DRAWINGS

FIG. 1 is a schematic view of the filtration and mixing apparatus of the present disclosure in a vapor generation and thin film deposition system

FIG. 2 is a schematic view of one embodiment of the apparatus of the present disclosure;

FIG. 3 is a sectional view A-A of the embodiment of the apparatus of FIG. 2;

FIG. 4 is a schematic view of a second embodiment of the apparatus of the present disclosure; and

FIG. 5 is a schematic view of a third embodiment of the apparatus of the present disclosure.

### DESCRIPTION OF THE EXEMPLARY EMBODIMENTS

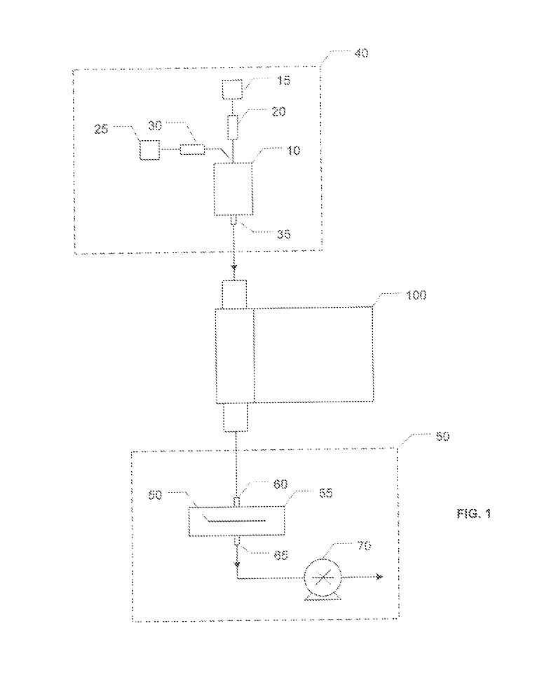

FIG. 1 shows the filtration and mixing apparatus of the present disclosure placed between a precursor vaporization system, shown generally at 40, and a thin film deposition system shown generally at 50. The vaporization system 40 includes a vaporizer 10, which is supplied with a carrier gas from source 15 through a gas flow controller 20, and a precursor liquid supply system comprised of a liquid source 25 and a liquid flow controller 30. The vaporizer is heated to a suitably high temperature to permit the liquid precursor flowing into the system to become vaporized, while at the same time the carrier gas flowing into the system also becomes heated to substantially the same temperature as the vapor. The resulting gas and vapor then flow out of the vaporizer as a gas/vapor mixture through outlet 35.

The thin film deposition system shown generally at 50 is comprised of a deposition chamber 55 containing a wafer 50 on which thin film is to be deposited. Commonly used deposition processes used for fabricating integrated circuit device chips on wafers include CVD, PE-CVD, ALD, among others. The deposition chamber 55 is provided with an inlet 60 through which the gas/vapor mixture can enter and an outlet 65 through which the gas/vapor mixture can exit to the vacuum pump 70 located downstream of the deposition chamber. The system is usually provided with electronic controls so that the chamber can be maintained at a proper pressure, and the wafer contained therein and the chamber itself can be maintained at their respective temperatures suitable for the optimal formation of thin films on the wafer.

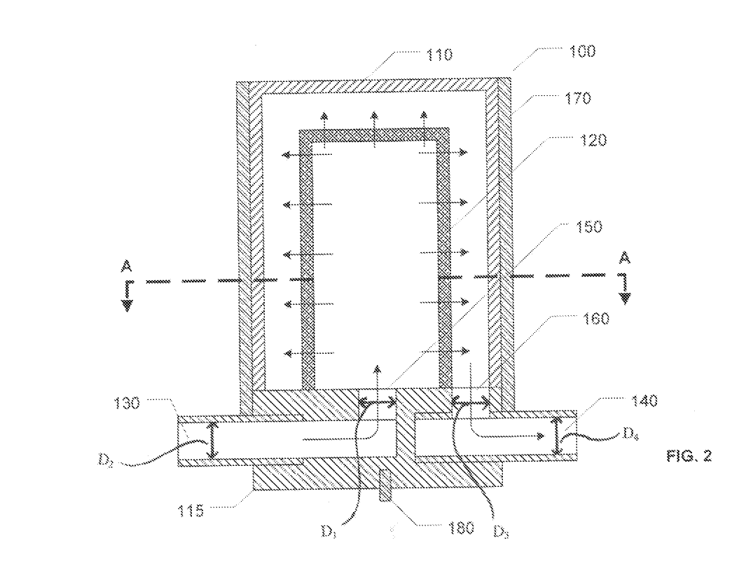

FIG. 2 shows one embodiment of the present disclosure. It includes an enclosure 110 formed over a base 115 containing a filter element 120. Enclosure 110 is usually welded to base 115 to form a vacuum tight system. It is provided with an inlet flow passageway 130 and an outlet flow passageway 140 in base 115 for the gas/vapor mixture to enter and exit. There is an opening in the form of an orifice 150 in an angular relationship with inlet flow passageway 130. The preferred angle is approximately 90 degrees so that the gas/vapor mixture flowing through passageway 130 can be directed to make an approximate 90-degree turn and flow to one side of the filter element 120. The gas/vapor mixture issuing from orifice 130 forms a turbulent jet to provide additional turbulent gas mixing for the gas/vapor mixture. The filter element is porous in nature, and is generally welded to base 115. The gas/vapor mixture can flow through the interstitial pore space of the porous filter to remove the gas-borne particulate matter. The gas/vapor mixture passing through the filter element 120, therefore, will become pure and substantially free of particulate contaminants. This purified gas/vapor stream then passes through another opening, 160, which is in the form of an orifice. Orifice 160 is also at an angular relationship, usually at an approximate right angle, with the exit flow passageway 140. This angular relationship forces the gas/vapor mixture to undergo yet another approximate 90-degree turn before exiting the apparatus through outlet passageway 140.

For the proper functioning of the apparatus, diameter, D₁, of orifice 150 must not be too small or too large compared to the diameter, D₂, of the inlet passageway 130. A small D₁ will provide good mixing, but can cause too high a pressure drop. A large D₁ will reduce the overall pressure drop through the apparatus, but may provide inadequate mixing of the gas/vapor mixture stream. For the proper functioning of the apparatus the ratio D₁/D₂ is usually kept between approximately 0.5 and 2.0. Similarly, the ratio D₃/D₄ of the diameter, D₃, of orifice 160 and the diameter, D₄, of the exit flow passageway 140, is also kept within proper limits, typically between approximately 0.5 and 2.0.

The apparatus is generally provided with an electric heater 170 and a temperature sensor 180. By means of electronic controls (not shown), the entire apparatus can be heated to a suitably high and substantially uniform temperature to prevent vapor condensation inside the apparatus. The operating temperature of the apparatus is usually the same or somewhat higher than the set-point temperature of vaporizer 10 shown in FIG. 1.

Since thin film deposition often occurs under vacuum conditions, the entire apparatus must also be vacuum tight to prevent leakage of ambient air into the system. To meet these requirements, the apparatus is usually constructed of stainless steel and all parts are welded together to permit high temperature and vacuum tight operations.

In the absence of apparatus 100 of the present disclosure placed between the vapor generation system 40 and the film deposition system 50 in FIG. 1, the gas/vapor will flow directly through a connecting tube from the outlet 35 of vaporizer 10 to the inlet 60 of the deposition chamber. The mixture flow through this connecting tubing is usually laminar in nature. Turbulent mixing usually does not occur to a significant degree. If the gas/vapor mixture is not uniformly mixed when it leaves outlet 35 of vaporizer 10 it will generally remain non-uniformly mixed when it enters the deposition chamber 55 through inlet 60. This non-uniformity in gas/vapor mixing can cause non-uniform film thickness to develop on the wafer to affect the quality of the device being fabricated and potentially lead to a product yield loss.

In gas flow through circular tubes, the nature of the gas flow is determined by the Reynolds number. The Reynolds number, Re, is defined as:

$$Re = \frac{VD ρ}{μ}$$

where V is the velocity of the gas through the tube, D is the diameter of the tube, ρ is the density of the gas, and μ is the viscosity of the gas. For example, for a gas flow of 1 standard liter per minute (slm) of nitrogen through a tube of ½″ in diameter, the Reynolds number is approximately 100. In fluid flow through tubes, the transition from laminar to turbulent flow will usually occur around a Reynolds number of 2300. A Reynolds number below 2300 will usually lead to a laminar flow in the tube. A Reynolds number above 2300 will usually cause fluid turbulence to develop leading to a turbulent flow in the tube. At the Reynolds number of 100, the flow is thus laminar.

Gas flow in thin film deposition apparatus can be higher than the 1.0 slm value cited in the above example. In some processes, gas flow can be as high as 10 slm. Even at 10 slm the Reynolds number is still around 1,000. The flow is likely to remain laminar. Only when the gas flow reaches the >20 slm range, condition of turbulent flow may develop.

In laminar flow, gas and vapor cannot mix effectively. Mixing can still occur through the process of molecular inter-diffusion. But molecular inter-diffusion is a much slower process than turbulent mixing and often would not be sufficient to provide the truly uniform mixing requirements of the semiconductor industry involved in the high volume commercial fabrication of integrated circuit devices.

In the apparatus of FIG. 2, mixing occurs when the mixture is forced to undergo an approximate 90° turn in flow direction through orifice 150 and 160. When the gas flow is at a sufficiently high velocity and turning at the same time, centrifugal force will develop to cause the gas to develop counter-rotating vortices that can lead to improved mixing of the gas and vapor in the mixture flow. In addition, when the gas flows through orifice 160 into the empty space inside the filter element 120, it would form a gas jet which will rapidly decelerate to produce turbulent mixing. By this means, the uniformity of the mixture is improved while the mixture is passing through the apparatus for particle removal.

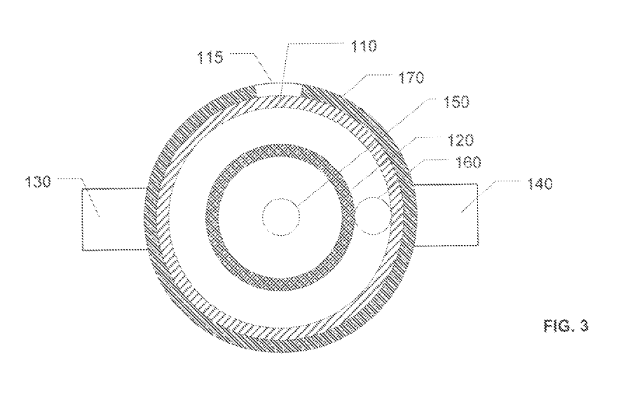

FIG. 3 is a sectional view along the line A-A of FIG. 2. In FIG. 3, the individual components are labeled with the same reference numbers as in FIG. 2. The cylindrical enclosure is thus labeled as 110, the filter element is labeled 120, the tubes containing the inlet and outlet gas flow passageways are labeled 130 and 140, the orifices are labeled 150 and 160, and the electrical heater around the cylindrical enclosure 110 is labeled 170.

In order to heat the enclosure 110 uniformly, a band heater is used for 170. The band heater is made in the form of a metal band with a gap 115 allowing it to be placed around the enclosure 110 and tightened by screws (not shown) tightly around the enclosure. This creates good thermal contact between the heater and the enclosure to improve the thermal response of the system.

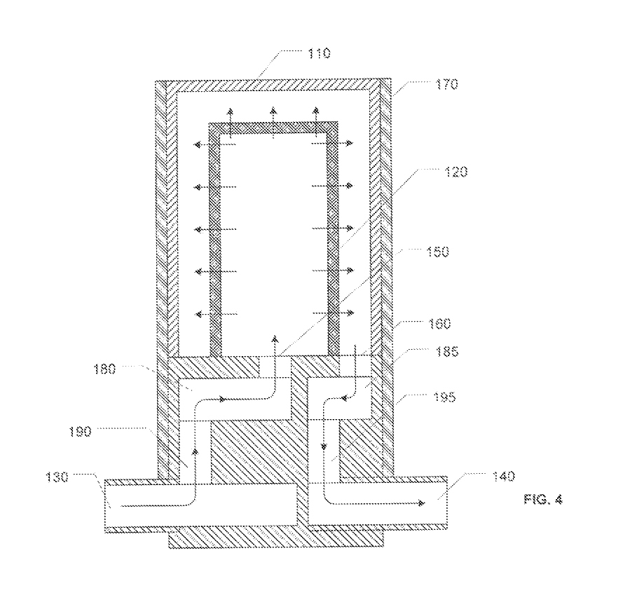

FIG. 4 is a second embodiment of the present disclosure. Again all parts of the system are similarly labeled as in FIGS. 2 and 3. In this embodiment, additional flow passageways are provided. Gas entering the apparatus through inlet 130 first flows upward through a cylindrical passageway 190. The gas then flows through a horizontal cylindrical passageway 180 before the gas flows through orifice 150 into the cavity inside the filter element 120. The gas then exits the downstream side of the filter element through orifice 160. The gas then flows through a horizontal cylindrical flow passageway 185 and a vertical cylindrical flow passageway 195 before it flows out the apparatus through outlet flow passageway 140.

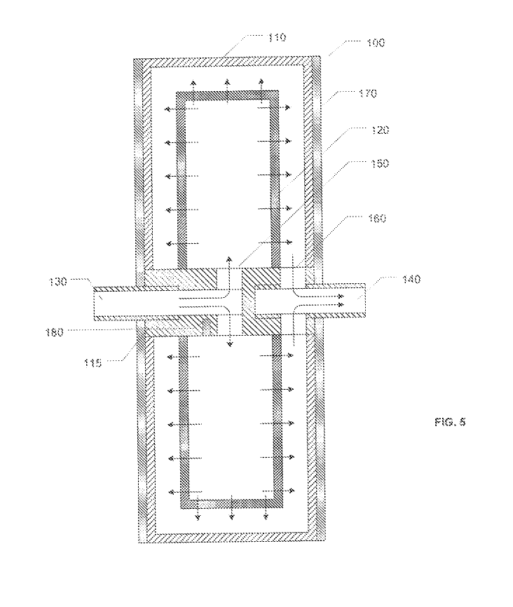

FIG. 5 is a third embodiment of the present disclosure. The third embodiment is comprised of two nearly identically constructed systems similar to the system 100 shown in FIG. 2. The two systems are placed end to end and share the same common inlet 130 and outlet 140 and the same base 115 on which the two identical enclosures with the respective filter elements are welded to form a single filter with twice the filter area and twice the flow capacity of the individual systems.

This disclosure describes a basic approach to designing filtration and mixing apparatus based on an understanding of the requirements of thin film deposition and semiconductor integrated circuit device fabrication and a fundamental understanding of the fluid mechanics of filtration and fluid flow. Those skilled in the art of filter and filtration system design will recognize the improvements that have been made in this disclosure based the approach and apply it to other possible designs that do not fundamentally differ from the one described here. These addition possible designs will not be further described.

1. An apparatus for particle filtration and gas/vapor mixing for thin film deposition on a substrate, the apparatus comprising:
a first enclosure containing a first porous filter element for particle filtration, a base having an inlet and an outlet flow passageway for a mixture of gas and vapor to enter and exit with the enclosure being attached to the base, said mixture being generated by a vaporization apparatus generating a vapor from a liquid precursor for thin film deposition and producing a heated output gas/vapor mixture stream;
said apparatus further including an orifice in an angular relationship with each of the inlet and outlet gas flow passageways, the orifice and the inlet and the outlet gas flow passageways are configured to causes (1) the gas/vapor mixture to undergo a substantial change in flow direction to cause mixing of the gas/vapor mixture by virtue of centrifugal force generated by the change in the flow direction of said gas/vapor mixture or (2) the formation of a gas jet that produces mixing due to flow deceleration.

2. The apparatus of claim 1 with said angular relationship between said orifice and said flow passageway being a right-angle relationship not substantially different from approximately 90 degrees.

3. The apparatus of claim 1 having a ratio of the diameter of the said orifice and the diameter of said flow passageway adjacent to said orifice between approximately 0.5 and 2.0.

4. The apparatus of claim 2 with additional gas flow passageways to cause the gas/vapor flow in the system to undergo a total of six (6) approximately right angle turns for a total angular turn of approximately 540 degrees to promote the mixing of gas/vapor mixture in the system.

5. The apparatus of claim 1, said porous filter element being made of metal.

6. The apparatus of claim 1, said filter element being made of stainless steel.

7. The apparatus of claim 1 including a mechanism for temperature control to prevent vapor condensation in said apparatus, said mechanism including an electric heater and a temperature sensor.

8. The apparatus of claim 7 wherein said electric heater comprises a band heater in intimate thermal contact with said enclosure.

9. The apparatus of claim 1 including a vaporization apparatus, said vaporization apparatus including a gas source and a liquid source for generating a mixture of vapor and gas.

10. The apparatus of claim 9 including a deposition chamber for forming a thin film on a substrate.

11. The apparatus of claim 10 wherein said substrate comprises a wafer.

12. The apparatus of claim 11 wherein said wafer is being used to form semiconductor integrated circuit devices.

13. The apparatus of claim 1 and further including a second enclosure containing a second porous filter element being attached to the base on a side opposite from the first enclosure with the second enclosure in gas flow communication with the inlet and outlet flow passageway of the base thereby increasing the flow capacity of the apparatus.

14. The apparatus of claim 1 wherein the filter element is constructed of a material capable of being welded to the metal base.

15. The apparatus of claim 14 wherein the filter element comprises a sintered powdered metal filter or a metal filter fiber, the metal being stainless steel.
